(19) United States
(12) Patent Application Publication
(10) Pub. No.: US 2018/0144973 A1
(43) Pub. Date: May 24, 2018

(54) Electromigration Improvement Using Tungsten For Selective Cobalt Deposition On Copper Surfaces

(71) Applicant: Applied Materials, Inc., Santa Clara, CA (US)

(72) Inventors: Weifeng Ye, San Jose, CA (US); Jiang Lu, Milpitas, CA (US); Feng Chen, San Jose, CA (US); Zhiyuan Wu, San Jose, CA (US); Kai Wu, Palo Alto, CA (US); Vikash Banthia, Los Altos, CA (US); He Ren, San Jose, CA (US); Sang Ho Yu, Cupertino, CA (US); Mei Chang, Saratoga, CA (US); Feiyue Ma, Sunnyvale, CA (US); Yu Lei, Belmont, CA (US); Keyvan Kashefizadeh, Dublin, CA (US); Kevin Moraes, Fremont, CA (US); Paul F. Ma, Santa Clara, CA (US); Hua Ai, Tracy, CA (US)

(21) Appl. No.: 15/800,784

(22) Filed: Nov. 1, 2017

Related U.S. Application Data
(60) Provisional application No. 62/415,852, filed on Nov. 1, 2016.

(51) Int. Cl. H01L 21/768; H01L 21/02; H01L 23/532; H01L 23/522

(52) U.S. Cl. CPC H01L 21/7685; H01L 21/76877; H01L 23/5226; H01L 21/02068; H01L 23/53238; H01L 21/76834

(57) ABSTRACT

Methods to selectively deposit capping layers on a copper surface relative to a dielectric surface comprising separately the copper surface to a cobalt precursor gas and a tungsten precursor gas, each in a separate processing chamber. The copper surface and the dielectric surfaces can be substantially coplanar. The combined thickness of cobalt and tungsten capping films is in the range of about 2 Å to about 60 Å.

### FIELD

Embodiments of the disclosure generally relate to methods of selectively depositing one or more capping layers. More particularly, embodiments of the disclosure are directed to methods of selectively depositing both cobalt and tungsten films each in a separate chamber onto a copper surface.

### BACKGROUND

Copper is used in multilevel metallization processes in semiconductor device manufacturing. Multilevel interconnects that drive the manufacturing processes utilize planarization of high aspect ratio apertures including contacts, vias, lines, and other features. Filling the features without creating voids or deforming the feature geometry is more difficult when the features have higher aspect ratios. Reliable formation of interconnects is also more difficult as manufacturers strive to increase circuit density and quality.

Several processing methods have been developed to manufacture copper interconnects as feature sizes have decreased. Each processing method may increase the likelihood of errors such as copper diffusion across boundary regions, copper crystalline structure deformation, and dewetting. Physical vapor deposition (PVD), chemical vapor deposition (CVD), atomic layer deposition (ALD), chemical mechanical polishing (CMP), electrochemical plating (ECP), electrochemical mechanical polishing (ECMP), and other methods of depositing and removing copper layers utilize mechanical, electrical, or chemical methods to manipulate the copper that forms the interconnects. Barrier and capping layers may be deposited to contain the copper. Improving boundary regions between copper and dielectric material is an ongoing goal.

Selective cobalt capping (US20090269507) improved electromigration (EM) performance by inserting the adhesion enhanced cobalt between copper and dielectric barrier/etch stop layers such as SiCN/SiN/SiOC/AlN. There is a continuing need to block copper diffusion paths.

As node sizes are reduced to 5 nm, capping thicknesses need to be correspondingly thinner (e.g., ˜1-2 nm) and remain continuous while still providing capping properties. There is a need to provide such capping layers.

### SUMMARY

One or more embodiments of the disclosure are directed to methods of capping a copper surface on a substrate. The substrate is positioned within a pre-treatment processing chamber, wherein the substrate comprises a copper oxide surface and a dielectric surface. The substrate is exposed within the pre-treatment processing chamber to a reducing agent to remove contaminants while forming a metallic copper surface during a pre-treatment process. The substrate is moved to a first vapor deposition processing chamber and exposing the substrate to a first precursor gas comprising one of cobalt or tungsten to selectively form a first capping layer over the metallic copper surface while leaving exposed the dielectric surface during a vapor deposition process. The substrate is moved to a second vapor deposition processing chamber and exposing the substrate to a second precursor gas comprising the other of cobalt or tungsten to selectively form a second capping layer over the first capping layer while leaving exposed the dielectric surface during a vapor deposition process.

Additional embodiments of the disclosure are directed to methods of capping a copper surface on a substrate. The substrate is positioned within a pre-treatment processing chamber, wherein the substrate comprises a copper oxide surface and a dielectric surface. The substrate is exposed within the pre-treatment processing chamber to a reducing agent to remove contaminants while forming a metallic copper surface during a pre-treatment process. The substrate is moved to a cobalt vapor deposition processing chamber and exposing the substrate to a cobalt-containing precursor gas to selectively form a cobalt capping film having a selectivity greater than or equal to about 50:1 over the metallic copper surface while leaving exposed the dielectric surface during a vapor deposition process. The substrate is then moved to a tungsten vapor deposition processing chamber and exposing the substrate to a tungsten-containing precursor gas to selectively form a tungsten capping film having a selectivity greater than or equal to about 50:1 over the metallic copper surface either above or below the cobalt capping film while leaving exposed the dielectric surface during a vapor deposition process. The substrate is moved to a third vapor deposition processing chamber and depositing a dielectric barrier layer over the tungsten capping film and the dielectric surface. A combined thickness of the cobalt and tungsten capping films is in the range of about 2 Å to about 60 Å.

Further embodiments of the disclosure are directed to methods of capping a copper surface on a substrate. A substrate having a copper surface and a dielectric surface is provided, the copper surface and the dielectric surface being substantially coplanar. Optionally the substrate is pre-treated and/or passivated to form a pre-cleaned and/or passivated substrate. In a chamber separate from the pre-treating and/or passivating, the substrate is exposed to vapor deposition conditions to deposit a cobalt film with a selectivity greater than or equal to about 50:1 on the copper surface relative to the dielectric surface, deposition conditions comprising a thermal CVD process using cyclopentadienyl cobalt bis(carbonyl) and hydrogen at a temperature in the range of about 200° C. to 400° C. In a chamber separate from deposition of the cobalt film, the substrate is exposed to vapor deposition conditions to deposit a tungsten film with a selectivity of greater than or equal to about 50:1 on the cobalt film relative to the dielectric surface, the deposition conditions comprising a thermal CVD process using WF₆/H₂ at a temperature in the range of about 200° C. to about 350° C.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 shows a cluster tool in accordance with one or more embodiments of the disclosure;

FIG. 2 shows a process flow diagram of a process in accordance with one or more embodiments of the disclosure;

FIGS. 3A-3B show a schematic cross-sectional view of a substrate with two capping layers deposited on a copper surface in accordance with one or more embodiments of the disclosure; and

FIG. 4 is Transmission Electron Microscope (TEM) images of portion of a substrate after formation of tungsten capping layer where there is a 40 Å layer of tungsten on a 20 Å layer of cobalt, which is on a copper surface.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

Embodiments of the disclosure provide methods to selective capping a copper surface on a substrate using a cluster tool. The methods involve exposing the copper surface to a cobalt precursor gas and a tungsten precursor gas, each in a separate chamber. The resulting capping layers may be a tungsten film on top of a cobalt film, which is on top of the copper surface; or they may be a cobalt film on top of a tungsten film, which is on top of the copper surface.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used. In one or more embodiments, the first substrate surface will comprise a metal, and the second substrate surface will comprise a dielectric, or vice versa. In some embodiments, a substrate surface may comprise certain functionality (e.g., —OH, —NH, etc.).

As used in this specification and the appended claims, the terms “reactive gas”, “precursor”, “reactant”, and the like, are used interchangeably to mean a gas that includes a species which is reactive with a substrate surface. For example, a first “reactive gas” may simply adsorb onto the surface of a substrate and be available for further chemical reaction with a second reactive gas.

Embodiments of the disclosure provide methods of selectively forming a capping layer over a dielectric surface. As used in this specification and the appended claims, the term “selectively forming” a film on one surface over another surface, and the like, means that a first amount of the film is deposited on the first surface and a second amount of film is deposited on the second surface, where the second amount of film is less than the first amount of film or none. The term “over” used in this regard does not imply a physical orientation of one surface on top of another surface, rather a relationship of the thermodynamic or kinetic properties of the chemical reaction with one surface relative to the other surface. For example, selectively depositing a cobalt film onto a copper surface over a dielectric surface means that the cobalt film deposits on the copper surface and less or no cobalt film deposits on the dielectric surface; or that the formation of the cobalt film on the copper surface is thermodynamically or kinetically favorable relative to the formation of a cobalt film on the dielectric surface. Stated differently, the film can be selectively deposited onto a first surface relative to a second surface means that deposition on the first surface is favorable relative to the deposition on the second surface.

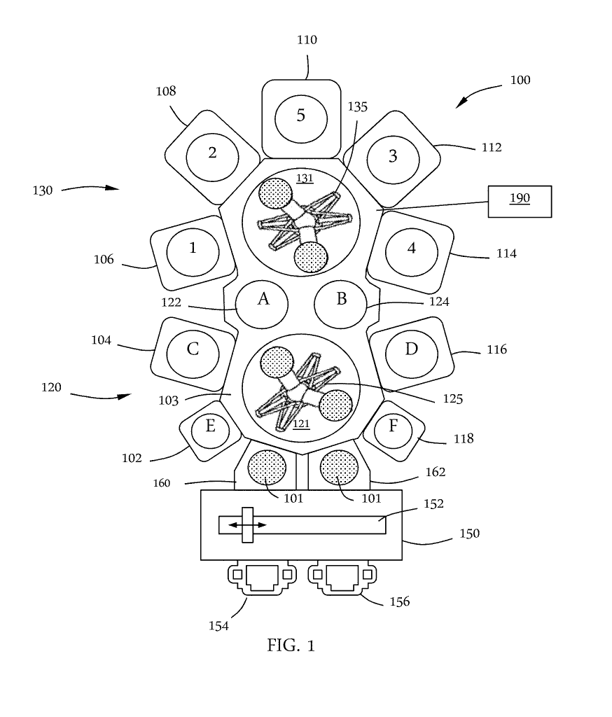

FIG. 1 shows a schematic diagram of an illustrative multiple chamber semiconductor processing tool, also referred to as a cluster tool or multi-cluster tool. The cluster tool 100 comprises a plurality of processing chambers 102, 104, 106, 108, 110, 112, 114, 116, 118. The various processing chambers can be any suitable chamber including, but not limited to, a pre-clean or passivation chamber, a pre-treatment chamber, a vapor deposition chamber, a buffer chamber, transfer space(s), a wafer orienter/degas chamber, a cooldown chamber, and a transfer chamber. The particular arrangement of process chambers and components can be varied depending on the cluster tool and should not be taken as limiting the scope of the disclosure.

In the embodiment shown in FIG. 1, a factory interface 150 is connected to a front of the cluster tool 100. The factory interface 150 includes a loading chamber 154 and an unloading chamber 156 on a front 151 of the factory interface 150. While the loading chamber 154 is shown on the left and the unloading chamber 156 is shown on the right, those skilled in the art will understand that this is merely representative of one possible configuration.

The size and shape of the loading chamber 154 and unloading chamber 156 can vary depending on, for example, the substrates being processed in the cluster tool 100. In the embodiment shown, the loading chamber 154 and unloading chamber 156 are sized to hold a wafer cassette with a plurality of wafers positioned within the cassette.

A robot 152 is within the factory interface 150 and can move between the loading chamber 154 and the unloading chamber 156. The robot 152 is capable of transferring a wafer from a cassette in the loading chamber 154 through the factory interface 150 to load lock chamber 160. The robot 152 is also capable of transferring a wafer from the load lock chamber 162 through the factory interface 150 to a cassette in the unloading chamber 156. As will be understood by those skilled in the art, the factory interface 150 can have more than one robot 152. For example, the factory interface 150 may have a first robot that transfers wafers between the loading chamber 154 and load lock chamber 160, and a second robot that transfers wafers between the load lock 162 and the unloading chamber 156.

The cluster tool 100 shown has a first section 120 and a second section 130. The first section 120 is connected to the factory interface 150 through load lock chambers 160, 162. The first section 120 includes a first transfer chamber 121 with at least one robot 125 positioned therein. The robot 125 is also referred to as a robotic wafer transport mechanism. The first transfer chamber 121 is centrally located with respect to the load lock chambers 160, 162, process chambers 102, 104, 116, 118 and buffer chambers 122, 124. The robot 125 of some embodiments is a multi-arm robot capable of independently moving more than one wafer at a time. In some embodiments, the first transfer chamber 121 comprises more than one robotic wafer transfer mechanism. The robot 125 in first transfer chamber 121 is configured to move wafers between the chambers around the first transfer chamber 121. Individual wafers are carried upon a wafer transport blade that is located at a distal end of the first robotic mechanism.

After processing a wafer in the first section 120, the wafer can be passed to the second section 130 through a pass-through chamber. For example, chambers 122, 124 can be uni-directional or bi-directional pass-through chambers. The pass-through chambers 122, 124 can be used, for example, to pre-clean or preheat the wafer before processing in the second section 130, or allow wafer cooling or post-processing before moving back to the first section 120.

The cluster tool 100 may comprise a body 103 with a first section 120 and a second section 130. The first section 120 includes a first central transfer chamber 121 and a first plurality of processing chambers 102, 104, 116, 118. Each of the first plurality of processing chambers is connected to the first central transfer chamber 121 and is accessible by a first robot 125 located in the first central transfer chamber 121. The second section 130 includes a second central transfer chamber 131 and a second plurality of processing chambers 106, 108, 110, 112, 114. Each of the second plurality of processing chambers is connected to the second central transfer chamber 131 and is accessible by a second robot 135 located in the second central transfer chamber 131.

A system controller 190 is in communication with the first robot 125, second robot 135, first plurality of processing chambers 102, 104, 116, 118 and second plurality of processing chambers 106, 108, 110, 112, 114. The system controller 190 can be any suitable component that can control the processing chambers and robots. For example, the system controller 190 can be a computer including a central processing unit, memory, suitable circuits and storage.

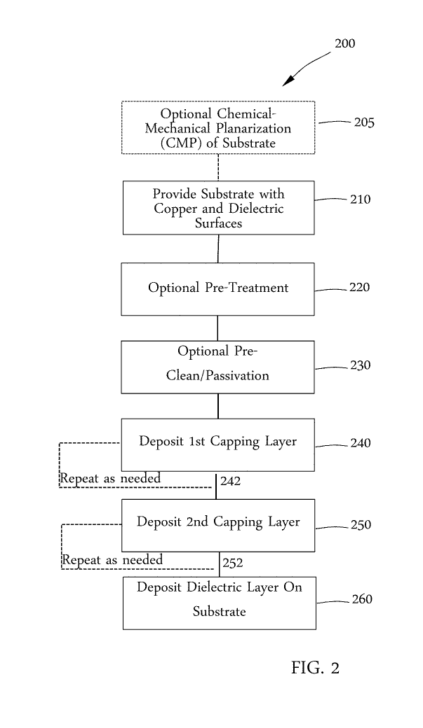

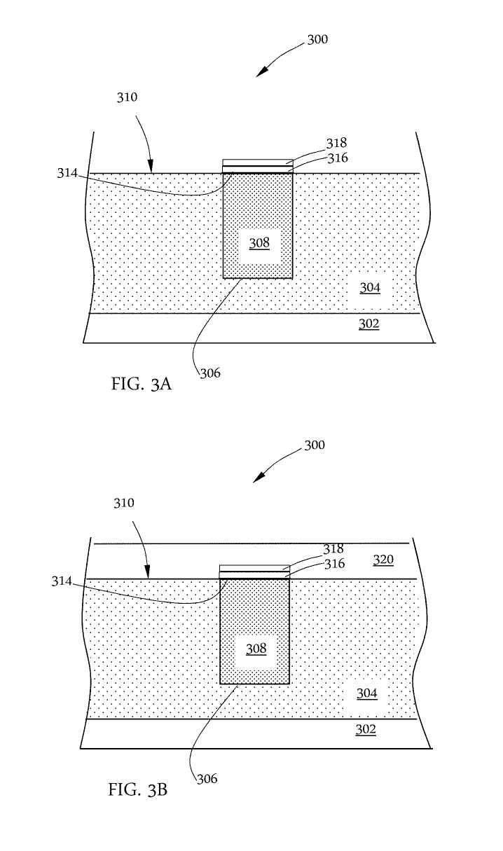

Embodiments of the disclosure are directed to methods of capping a copper surface utilizing different chambers of a cluster tool. FIG. 2 shows a process flow diagram a process 200 in accordance with one or more embodiments of the disclosure. With reference to FIGS. 2 and 3A-3B, a substrate 300 containing dielectric layer 304 disposed over underlayer 302 comprising a copper surface 314 of a copper interconnect 308 and a dielectric surface 310 is provided for processing at 210. As used in this regard, the term “provided” means that the substrate is placed into a position or environment for further processing.

Copper interconnects 308 are disposed within dielectric layer 304 and are separated from dielectric layer 304 by barrier layer 306. Dielectric layer 304 contains a dielectric material, such as a low-k dielectric material. In one example, dielectric layer 304 contains a low-k dielectric material, such as a silicon carbide oxide material or a carbon doped silicon oxide material, for example, BLACK DIAMOND® II low-k dielectric material, available from Applied Materials, Inc., located in Santa Clara, Calif.

Barrier layer 306 may be conformally deposited into the aperture within dielectric layer 304. Barrier layer 306 may be formed or deposited by a PVD process, an ALD, or a CVD process, and may have a thickness within a range from about 5 Å to about 50 Å, preferably, from about 10 Å to about 30 Å. Barrier layer 306 may contain titanium, titanium nitride, tantalum, tantalum nitride, tungsten, tungsten nitride, derivatives thereof, or combinations thereof. In some embodiments, barrier layer 306 may contain a tantalum/tantalum nitride bilayer or titanium/titanium nitride bilayer. In one example, barrier layer 306 contains tantalum nitride and metallic tantalum layers deposited by PVD processes.

In some embodiments, as shown in FIGS. 3A-3B, the copper surface and the dielectric surface are substantially coplanar. Those skilled in the art will understand that substantially coplanar means that the major planes formed by individual surface are within about the same plane. As used in this regard, “substantially coplanar” means that the plane formed by the first surface is within ±100 μm of the plane formed by the second surface, measured at the boundary between the first surface and the second surface. In some embodiments, the planes formed by the first surface and the second surface are within ±500 μm, ±400 μm, ±300 μm, ±200 μm, ±100 μm, ±50 μm, ±10 μm, ±5 μm, ±1 μm, ±500 nm, ±250 nm, ±100 nm, ±50 nm, ±10 nm, ±1 nm or ±0.1 nm.

In some embodiments, the substrate 300 has been subjected to a chemical-mechanical planarization (CMP) process at 205. A CMP process may cause the surfaces to become oxidized, contaminated or damaged. The oxidation, contamination or damage to the surface can result in the loss in selectivity. The surface of the substrate, including the copper surface and the dielectric surface, may have a root-mean-square (RMS) roughness less than or equal to about 100 nm, 50 nm, 10 nm, 1 nm, 0.5 nm or 0.1 nm.

At 220, the substrate surfaces may optionally be exposed to a pre-treatment process in order to remove contaminants therefrom. Copper surface 314 is exposed once contaminants are treated or removed from the copper interconnect 308. Copper oxides may be chemically reduced by exposing substrate 300 to a reducing agent. The pre-treatment process exposes substrate 300 to the reducing agent during a thermal process or a plasma process. The reducing agent may have a liquid state, a gas state, a plasma state, or combinations thereof. Reducing agent that are useful during the pre-treatment process include hydrogen (e.g., H₂ or atomic-H), ammonia (NH₃), a hydrogen and ammonia mixture (H₂/NH₃), atomic-N, hydrazine (N₂H₄), alcohols (e.g., methanol, ethanol, or propanol), derivatives thereof, plasmas thereof, or combinations thereof. Substrate 200 may be exposed to a plasma formed in situ or remotely during the pre-treatment process.

In one embodiment, substrate 300 is exposed to a thermal pre-treatment process to remove contaminants from a copper interconnect 308 while forming a metallic copper surface 314. Substrate 300 may be positioned within a pre-treatment processing chamber, exposed to a reducing agent, and heated to a temperature within a range from about 200° C. to about 800° C., preferably, from about 250° C. to about 600° C., and more preferably, from about 300° C. to about 500° C. Substrate 300 may be heated for a time period within a range from about 2 minutes to about 20 minutes, preferably, from about 5 minutes to about 15 minutes. For example, substrate 300 may be heated to about 500° C. in a processing chamber containing a hydrogen atmosphere for about 12 minutes.

In another embodiment, substrate 300 is exposed to a plasma pre-treatment process to remove contaminants from a copper interconnect 308 while forming a metallic copper surface 314. Substrate 300 may be positioned within a pre-treatment processing chamber, exposed to a reducing agent, and heated to a temperature within a range from about 100° C. to about 400° C., preferably, from about 125° C. to about 350° C., and more preferably, from about 150° C. to about 300° C., such as about 200° C. or about 250° C. The processing chamber may produce an in situ plasma or be equipped with a remote plasma source (RPS). In one embodiment, substrate 300 may be exposed to the plasma (e.g., in situ or remotely) for a time period within a range from about 2 seconds to about 60 seconds, preferably, from about 3 seconds to about 30 seconds, preferably, from about 5 seconds to about 15 seconds, such as about 10 seconds. The plasma may be produced at a power within the range from about 200 watts to about 1,000 watts, preferably, from about 400 watts to about 800 watts. In one example, substrate 200 may be exposed to hydrogen gas while a plasma is generated at 400 watts for about 10 seconds at about 5 Torr. In another example, substrate 200 may be exposed to ammonia gas while a plasma is generated at 800 watts for about 20 seconds at about 5 Torr. In another example, substrate 200 may be exposed to a hydrogen and ammonia gaseous mixture while a plasma is generated at 400 watts for about 15 seconds at about 5 Torr.

After pre-treatment 220, to increase the selectivity, the substrate may be exposed to a pre-cleaning or passivation process 230. The term “pre-clean” means prior to deposition of the metal film on the surface without additional intervening processing steps (e.g., deposition, annealing, polishing). The pre-clean process may comprise exposing the substrate to a pre-clean plasma, which may comprise or consist essentially of one or more of argon or hydrogen. As used in this regard, the term “consists essentially of” means than the active plasma species is greater than or equal to about 95 atomic % of the stated component. In some embodiments, the pre-clean plasma is greater than or equal to about 96, 97, 98 or 99 atomic percent of the stated component.

The conditions of the pre-clean plasma can be modified depending on the specific surfaces being cleaning. The pressure of the pre-clean plasma in some embodiments is in the range of about 10 mTorr to about 1 Torr. The temperature of the pre-clean plasma of some embodiments is about room temperature (in the range of about 20° C. to about 25° C.).

In some embodiments, the pre-clean plasma includes a bias component applied to the substrate to cause more directionality to the plasma species. For example a bias of 2 MHz applied to the wafer (or pedestal or wafer support) may improve the selectivity of the metal film deposition by decreasing the amount of lateral film deposition.

At 240 to deposit a first capping layer, a first metal film 316 is deposited selectively on the copper surface 314 relative to the dielectric surface 310 in a first vapor deposition chamber. In some embodiments, substantially none of the first metal film 316 deposits on the dielectric surface 310. As used in this regard, “substantially none” means that less than about 5%, 4%, 3%, 2% or 1% of the metal film is deposited on the second surface, as a total weight of the metal film. The first metal film 316 may be a continuous layer or a discontinuous layer across copper surface 314, but is a continuous layer after multiple deposition cycles. Deposition of the first metal film by exposing the substrate to a first precursor gas may be repeated at needed 242 until a desired thickness is achieved. The first metal film 316 may be deposited having a thickness within a range from about 1 Å to about 10 Å, preferably, from about 2 Å to about 8 Å, more preferably, from about 4 Å to about 6 Å.

At 250 to deposit a second capping layer, a second metal film 318 is deposited selectively on the first metal film 316 relative to the dielectric surface 310 in a second vapor deposition chamber, which is separate from the first vapor deposition chamber. In some embodiments, substantially none of the second metal film 318 deposits on the dielectric surface 310. The second metal film 318 may be a continuous layer or a discontinuous layer across the first metal film 316, but is a continuous layer after multiple deposition cycles. Deposition of the second metal film by exposing the substrate to a second precursor gas may be repeated at needed 252 until a desired thickness is achieved. The second metal film 318 may be deposited having a thickness within a range from about 1 Å to about 10 Å, preferably, from about 2 Å to about 8 Å, more preferably, from about 4 Å to about 6 Å.

At 260, a dielectric layer 320 is deposited on the substrate.

The first metal film 316 deposited may comprise either cobalt or tungsten, and as will be discussed below, the second metal film 318 is the other of cobalt or tungsten. For example, the first metal film 316 may comprise or consist essentially of cobalt and the second metal film 318 may comprise or consist essentially of tungsten. Alternatively, the first metal film 316 may comprise or consist essentially of tungsten and the second metal film 318 may comprise or consist essentially of cobalt.

As used in this regard, the term “consists essentially of” means that the metal film is greater than or equal to about 95 atomic percent of the specified component. In some embodiments, the metal film is greater than about 96, 97, 98 or 99 atomic percent of the specified component. It is understood that the cobalt film may have tungsten therein and that the tungsten film may have cobalt therein.

For formation of the tungsten film, the tungsten can be deposited by a chemical vapor deposition (CVD) process using a suitable tungsten precursor and reactant. Suitable tungsten precursors include, but are not limited to, tungsten halides, organic tungsten and organometallic tungsten complexes. In some embodiments, the tungsten precursor comprises WF₆ and the reactant comprises H₂. In some embodiments, the CVD process occurs at a temperature in the range of about 200° C. to 350° C., and all ranges and subranges therebetween. In one or more embodiments, the CVD process is a thermal process which occurs without plasma enhancement.

For formation of the cobalt film, the cobalt may be deposited by thermal decomposition of a cobalt containing precursor carried by an inert gas. A reducing gas may be co-flowed or alternately pulsed into the processing chamber along with the cobalt precursor. The substrate may be heated to a temperature within a range from about 50° C. to about 600° C., preferably, from about 100° C. to about 500° C., and more preferably, from about 200° C. to about 400° C., and all ranges and subranges therebetween. Alternatively, the cobalt film may be deposited by exposing the substrate to a cobalt-containing precursor gas in an ALD or CVD process.

The cobalt precursor gas contains a cobalt precursor which has the general chemical formula (CO)ₓCo_{y}L_{z}, wherein X is 1, 2, 3, 4, 5, 6, 7, 8, 9, 10, 11, or 12; Y is 1, 2, 3, 4, or 5; Z is 1, 2, 3, 4, 5, 6, 7, or 8; and L is a ligand independently selected from cyclopentadienyl, alkylcyclopentadienyl, methylcyclopentadienyl, pentamethylcyclopentadienyl, pentadienyl, alkylpentadienyl, cyclobutadienyl, butadienyl, allyl, ethylene, propylene, alkenes, dialkenes, alkynes, nitrosyl, ammonia, derivatives thereof, or combinations thereof. The cobalt precursor gas may contain a cobalt precursor selected from the group consisting of tricarbonyl allyl cobalt, cyclopentadienyl cobalt bis(carbonyl), methylcyclopentadienyl cobalt bis(carbonyl), ethylcyclopentadienyl cobalt bis(carbonyl), pentamethylcyclopentadienyl cobalt bis(carbonyl), dicobalt octa(carbonyl), nitrosyl cobalt tris(carbonyl), bis(cyclopentadienyl) cobalt, (cyclopentadienyl) cobalt (cyclohexadienyl), cyclopentadienyl cobalt (1,3-hexadienyl), (cyclobutadienyl) cobalt (cyclopentadienyl), bis(methylcyclopentadienyl) cobalt, (cyclopentadienyl) cobalt (5-methylcyclopentadienyl), bis(ethylene) cobalt (pentamethylcyclopentadienyl), derivatives thereof, complexes thereof, plasmas thereof, or combinations thereof. In one example, the cobalt precursor contains cyclopentadienyl cobalt bis(carbonyl).

According to one or more embodiments, the substrate is subjected to processing prior to and/or after forming the capping layers. This processing can be performed in the same chamber or in one or more separate processing chambers. In some embodiments, the substrate is moved from the first chamber to a separate, second chamber for further processing. The substrate can be moved directly from the first chamber to the separate processing chamber, or the substrate can be moved from the first chamber to one or more transfer chambers, and then moved to the separate processing chamber. Accordingly, the processing apparatus may comprise multiple chambers in communication with a transfer station. An apparatus of this sort may be referred to as a “cluster tool” or “clustered system”, and the like, an example of which is provided in FIG. 1.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Cluster tools which may be adapted for the present disclosure are the Producer®, Centura® and the Endura®, all available from Applied Materials, Inc., of Santa Clara, Calif. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants after forming the layer on the surface of the substrate. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

During processing, the substrate can be heated or cooled. Such heating or cooling can be accomplished by any suitable means including, but not limited to, changing the temperature of the substrate support (e.g., susceptor) and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated continuously or in discreet steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

### EXAMPLES

### Example 1

In a cluster tool, selectivity of tungsten was demonstrated. A pretreatment step was conducted in a pre-treatment processing chamber in a hydrogen soak for 5 minutes at 400° C. Using a WF₆ precursor, tungsten was selectively deposited onto various surfaces in a tungsten vapor processing chamber at 300° C., 10 T, 50 sccm WF₆, and 8,000 sccm H₂. The following table provides the selective W thickness at constant conditions.

| Surface | Selective W Thickness, Å |
|---|---|
| SiO₂ | 1.00 |
| APF | 1.06 |
| (amorphous carbon film) | |
| W | 251.29 |
| Co | 131.03 |
| Cu | 37.65 |

### Example 2

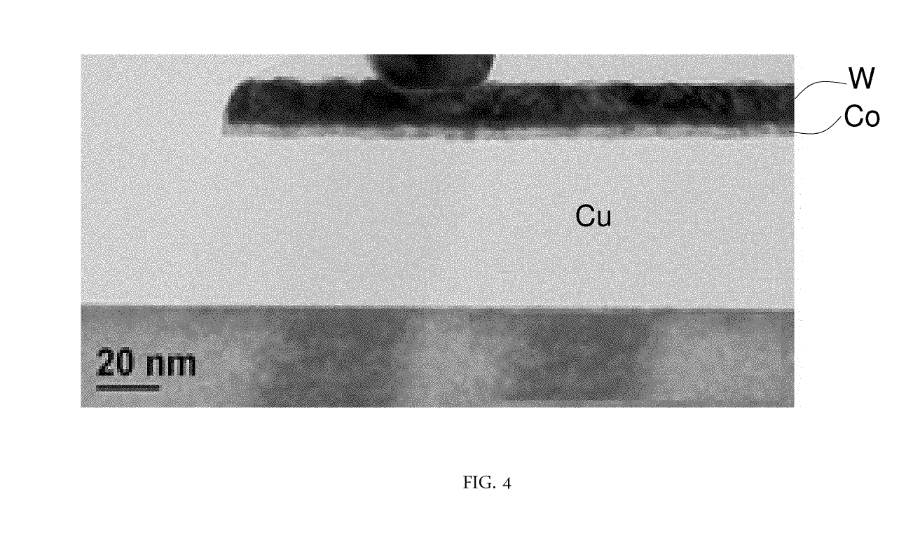

In a cluster tool, tungsten was selectively deposited in a layer having a thickness of 40 Å onto a 20 Å layer of cobalt, which was located on a metallic copper surface. A pretreatment step was conducted in a pre-treatment processing chamber in a hydrogen soak for 5 minutes at 400° C. Using a WF₆ precursor, tungsten was selectively deposited onto the cobalt layer in a tungsten vapor processing chamber at 300° C., 10 T, 50 sccm WF₆, and 8,000 sccm H₂. FIG. 4 is Transmission Electron Microscope (TEM) images of portion of a substrate after formation of tungsten capping layer where there is a 40 Å layer of tungsten on a 20 Å layer of cobalt, which is on a copper surface.

While the foregoing is directed to embodiments of the present disclosure, other and further embodiments of the disclosure may be devised without departing from the basic scope thereof, and the scope thereof is determined by the claims that follow.

What is claimed is:

1. A method of capping a copper surface on a substrate, the method comprising:
positioning the substrate within a pre-treatment processing chamber, wherein the substrate comprises a copper oxide surface and a dielectric surface;
exposing the substrate within the pre-treatment processing chamber to a reducing agent to remove contaminants while forming a metallic copper surface during a pre-treatment process;
moving the substrate to a first vapor deposition processing chamber and exposing the substrate to a first precursor gas comprising one of cobalt or tungsten to selectively form a first capping layer over the metallic copper surface while leaving exposed the dielectric surface during a vapor deposition process; and
moving the substrate to a second vapor deposition processing chamber and exposing the substrate to a second precursor gas comprising the other of cobalt or tungsten to selectively form a second capping layer over the first capping layer while leaving exposed the dielectric surface during a vapor deposition process.

2. The method of claim 1 further comprising moving the substrate to a third vapor deposition processing chamber and depositing a dielectric barrier layer over the second capping layer and the dielectric surface after the vapor deposition process in the second vapor deposition processing chamber.

3. The method of claim 1 further comprising moving the substrate to a passivation processing chamber and exposing the substrate to a process gas to passivate the dielectric surface before moving the substrate to the first vapor deposition processing chamber.

4. The method of claim 3, wherein the process gas is a pre-clean plasma comprising one or more of argon or hydrogen for removing oxides from the metallic copper surface.

5. The method of claim 1, wherein the first precursor gas comprises cobalt such that the first capping layer comprises a cobalt film and the second precursor gas comprises tungsten such that the second capping layer comprises a tungsten film.

6. The method of claim 1, wherein the first precursor gas comprises tungsten such that the first capping layer comprises a tungsten film and the second precursor gas comprises cobalt such that the second capping layer comprises a cobalt film.

7. The method of claim 1, wherein the copper oxide surface and the dielectric surface are substantially coplanar.

8. The method of claim 7, wherein the substrate has been subjected to a chemical-mechanical planarization process prior to positioning the substrate within the pre-treatment processing chamber.

9. The method of claim 1, wherein during the pre-treatment process a plasma is ignited, and the reducing agent comprises a reagent selected from the group consisting of nitrogen (N₂), ammonia (NH₃), hydrogen (H₂), ammonia/nitrogen mixture, and combinations thereof.

10. The method of claim 1, wherein the precursor gas comprising cobalt forms a cobalt film having a selectivity relative to the dielectric surface of greater than or equal to about 50:1.

11. The method of claim 1, wherein the precursor gas comprising tungsten forms a tungsten film having a selectivity relative to the dielectric surface of greater than or equal to about 50:1.

12. The method of claim 1, wherein the cobalt-containing precursor gas comprises cyclopentadienyl cobalt bis(carbonyl) and a cobalt film is formed by thermal CVD in the presence of hydrogen at a temperature in the range of about 200° C. to 400° C.

13. The method of claim 1, wherein the tungsten-containing precursor gas comprises WF₆ and a tungsten film is formed by CVD in the presence of H₂ at a temperature in the range of about 200° C. to 300° C. without plasma enhancement.

14. The method of claim 10, wherein the cobalt film has a thickness in the range of about 1 Å to about 10 Å.

15. The method of claim 11, wherein the tungsten film has a thickness in the range of about 1 Å to about 10 Å.

16. The method of claim 1, wherein a combined thickness of the first and second capping layers is in the range of about 2 Å to about 60 Å.

17. A method of capping a copper surface on a substrate, the method comprising:
positioning the substrate within a pre-treatment processing chamber, wherein the substrate comprises a copper oxide surface and a dielectric surface;
exposing the substrate within the pre-treatment processing chamber to a reducing agent to remove contaminants while forming a metallic copper surface during a pre-treatment process;
moving the substrate to a cobalt vapor deposition processing chamber and exposing the substrate to a cobalt-containing precursor gas to selectively form a cobalt capping film having a selectivity greater than or equal to about 50:1 over the metallic copper surface while leaving exposed the dielectric surface during a vapor deposition process;
moving the substrate to a tungsten vapor deposition processing chamber and exposing the substrate to a tungsten-containing precursor gas to selectively form a tungsten capping film having a selectivity greater than or equal to about 50:1 over the metallic copper surface either above or below the cobalt capping film while leaving exposed the dielectric surface during a vapor deposition process; and
moving the substrate to a third vapor deposition processing chamber and depositing a dielectric barrier layer over the tungsten capping film and the dielectric surface;
wherein a combined thickness of the cobalt and tungsten capping films is in the range of about 2 Å to about 60 Å.

18. The method of claim 17, wherein the tungsten capping film is below the cobalt capping film.

19. The method of claim 17, wherein the tungsten capping film is above the cobalt capping film.

20. A method of capping a copper surface on a substrate, the method comprising:
providing a substrate having a copper surface and a dielectric surface, the copper surface and the dielectric surface being substantially coplanar;
optionally pre-treating and/or passivating the substrate to form a pre-cleaned and/or passivated substrate;
in a chamber separate from the pre-treating and/or passivating, exposing the substrate to vapor deposition conditions to deposit a cobalt film with a selectivity greater than or equal to about 50:1 on the copper surface relative to the dielectric surface, deposition conditions comprising a thermal CVD process using cyclopentadienyl cobalt bis(carbonyl) and hydrogen at a temperature in the range of about 200° C. to 400° C.; and
in a chamber separate from deposition of the cobalt film, exposing the substrate to vapor deposition conditions to deposit a tungsten film with a selectivity of greater than or equal to about 50:1 on the cobalt film relative to the dielectric surface, the deposition conditions comprising a thermal CVD process using WF₆/H₂ at a temperature in the range of about 200° C. to about 300° C.
